(19) United States
(12) Patent Application Publication
(10) Pub. No.: US 2003/0137023 A1
(43) Pub. Date: Jul. 24, 2003

(54) Optoelectronic device, and method for producing an optoelectronic device

(76) Inventor: Bernhard Stegmuller, Augsburg (DE)

Correspondence Address: LERNER AND GREEBERG, P.A., POST OFFICE BOX 2480, HOLLYWOOD, FL, 33022-2480, US

(21) Appl. No.: 10/339,243

(22) Filed: Jan. 9, 2003

(30) Foreign Application Priority Data
Jan. 9, 2002 (DE) 102 01 124.9

(51) Int. Cl. H01L 31/0232; H01L 21/00; H01L 31/06

(52) U.S. Cl. 257/432; 438/69; 438/73; 257/461; 257/462

(57) ABSTRACT

An optoelectronic device has at least one quantum dot structure in a semiconductor material and at least two monolithically integrated components. At least two components are functionally coupled to one another in the semiconductor material via at least one quantum dot structure. This results in a very compact optoelectronic device.

### BACKGROUND OF THE INVENTION

### Field of the Invention

The invention relates to an optoelectronic device with at least one quantum dot structure in a semiconductor material and with at least two monolithically integrated components. The invention, furthermore, relates to a method for producing such an optoelectronic device.

Particularly in telecommunications, one problem that arises is the operation of ever smaller optoelectronic devices at every higher frequencies, in order to increase the data transmission rates.

It is known for two or more components of an optoelectronic device to be monolithically integrated on one substrate. Components such as these include, for example, laser diodes or electrooptical modulators (EO), for which multiple quantum wells (MQW) with different characteristics are used.

Devices such as these are known, for example, from the following literature references: K. Nakamura et al., “Buried Heterostructure DFB Laser Integrated with Ridge Waveguide Electroabsorption Modulator with over 29 GHz Bandwidth”, Proc. ECOC 97, Sep. 22-25, 1997, Conference Publication No. 488, IEE, 1997, pp. 175-78 and J. J. Coleman et al., “Progress in InGaAs-GaAs Selective-Area MOCVD Toward Photonic Circuits”, IEEE Journal of Selected Topics of Quantum Electronics, Vol. 3, No. 3, June 1997, pp. 874-84.

These devices have the disadvantage that the described devices can be produced only with a great deal of effort and in a number of epitaxy steps.

The devices which are described in A. Ramdane et al., “Monolithic Integration of Multiple-Quantum-Well Lasers and Modulators for High-Speed Transmission”, IEEE Journal of Selected Topics of Quantum Electronics, Vol. 2, No. 2, June 1996, pp. 326-35 or in my earlier U.S. Pat. No. 6,066,859 (corresp. DE 19652529 A1) are easier to produce, but their use is restricted. MQWs with the same quantum well types are described in the first case, and with different quantum well types in the second case.

### SUMMARY OF THE INVENTION

It is accordingly an object of the invention to provide an optoelectronic device, which overcomes the above-mentioned disadvantages of the heretofore-known devices and methods of this general type and which provides for a very compact optoelectronic device and a method for producing it easily.

With the foregoing and other objects in view there is provided, in accordance with the invention, an optoelectronic device, comprising:

a plurality of monolithically integrated components commonly integrated in semiconductor material; and

at least one quantum dot structure functionally coupling at least two of said monolithically integrated components to one another.

The functional coupling between at least two components (for example a laser diode and an electro-absorption modulator) in the semiconductor material via at least one quantum dot structure makes it possible to achieve very high data transmission rates.

In a quantum dot structure, the movements of the electrons with respect to quantum well structures are restricted even further; the electron movements are quantized in all three spatial directions. One major advantage of quantum dot structures is that the emission wavelength is not very dependent on the temperature, and this is of major importance for data transmission.

At least one component is advantageously functionally coupled to a further quantum dot structure or to a quantum well structure.

It is particularly advantageous to be able to produce at least one quantum dot structure and at least one quantum well structure in one epitaxy step. This allows the production cost to be minimized.

In accordance with an added feature of the invention, at least one component is in the form of a laser diode. In this case, in order to achieve narrowband laser light, it is advantageous for the laser diode to have a DFB structure (DFB, distributed feedback) or a DBR structure (DBR, distributed Bragg reflector).

It is also advantageous for at least one component to be in the form of an electro-absorption modulator. This allows radio-frequency modulation of the laser light.

In accordance with a further refinement, at least one component is in the form of an optical amplifier and/or photodetector.

For a high level of optical and/or electrical decoupling between at least two components, it is advantageous for at least one well to be incorporated in the semiconductor material, between the at least two components.

For a low level of optical decoupling and high level of electrical decoupling between at least two components, it is advantageous for at least one well to be incorporated in the semiconductor material, between the components, with this at least one well having implanted ions.

For a high level of optical and electrical decoupling between at least two components, at least one Bragg structure is advantageously arranged in the semiconductor material.

With the above and other objects in view there is also provided, in accordance with the invention, a method for producing the above-summarized optoelectronic device, which comprises:

providing a substrate;

in a single epitaxy step, growing a quantum dot structure as an active layer on the substrate and growing at least one of a further quantum dot structure and a further quantum well structure; and

wherein a plurality of monolithically integrated components are commonly integrated on the substrate and the quantum dot structure functionally couples at least two of the monolithically integrated components to one another.

In this case, a quantum dot structure is grown as an active layer on a substrate, with a further quantum dot structure and/or a further quantum dot structure being grown in the same epitaxy step. Growth in one epitaxy step makes it easier to produce the optoelectronic device.

Other features which are considered as characteristic for the invention are set forth in the appended claims.

Although the invention is illustrated and described herein as embodied in a optoelectronic device, and a method for its production, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic sectional view of a first embodiment of an optoelectronic device according to the invention;

FIG. 2 is a schematic sectional view of a second embodiment of the optoelectronic device according to the invention;

FIG. 3 is a schematic sectional view of a third embodiment of the optoelectronic device according to the invention;

FIG. 3A is a similar view showing a modification of the third embodiment of FIG. 3;

FIG. 4 is a schematic sectional view of a fourth embodiment of the optoelectronic device according to the invention; and

FIG. 4A is a similar view showing a modification of the fourth embodiment of FIG. 4.

### DESCRIPTION OF THE PREFERRED EMBODIMENTS

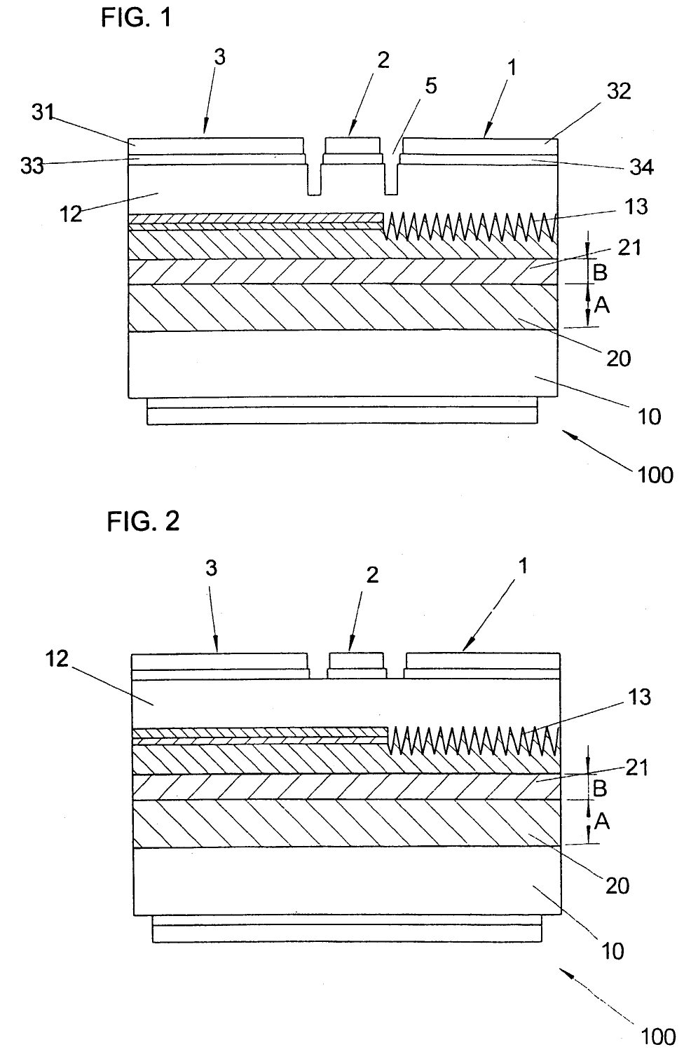

Referring now to the figures of the drawing in detail and first, particularly, to FIG. 1 thereof, there is shown a section taken through a first embodiment of an optoelectronic device 100 according to the invention. Seen from right to left, the components of this first embodiment are a laser diode 1, an electro-absorption modulator 2 (EAM), and an optical amplifier (semiconductor optical amplifier SOA) 3. All three components 1, 2, 3 are monolithically integrated with a semiconductor material.

The following text describes the horizontal sequence of the components 1, 2, 3 first of all, and then the vertical layer sequence.

The laser diode 1 is shown on the right in FIG. 1. Here, the laser diode 1 is in the form of a DFB laser with a Bragg grating 13. The Bragg grating 13 in this case is arranged only in the area of the laser diode 1. The Bragg grating 13 need not in this case extend over the entire length of the laser diode 1. In one alternative embodiment, a DBR laser structure may also be used.

The laser diode 1 is connected to the electro-absorption modulator 2, with a first well 5 being incorporated in the semiconductor material between the area of the laser diode 1 and the electro-absorption modulator 2. The electro-absorption modulator 2 makes it possible to influence the band structure of the semiconductor by varying the electric field, so that the intensity of the laser light from the laser diode 1 can be controlled. This modulation allows data transmissions at very high frequencies. In principle, it is also possible to use other electrooptical modulators.

The electro-absorption modulator 2 is connected to an area for an optical amplifier 3 in a manner known per se. A second well 6 is arranged between the electro-absorption modulator 2 and the optical amplifier 3.

The electrooptical device 100 is formed on layers 10. In this case, the layers are deposited epitaxially in a conventional way, and are structured, for example, by etching.

An MQW layer is grown as a modulator layer 20 on n-doped, epitaxially grown layers 10 forming a substrate, and is intended for the electro-absorption modulator 2. The thickness A of the modulator layer 20 is between approximately 0 and 500 nm.

A quantum dot structure 21 (QD) is arranged as an active layer for the laser diode 1. The quantum dot structure 21 has a thickness B of approximately 0 to 500 nm.

The ratio of the layer thicknesses expressed as B/(A+B) is greater than 0 and maximally 1. The minimum value would then correspond to a virtually pure quantum well structure, while the maximum value would correspond to a pure quantum dot structure.

In this first embodiment and in contrast with prior art integrated structures, the components 1, 2, 3 of the optoelectronic device 100 are functionally coupled via the quantum dot structures 21 and the MQW structure 20. The quantum dot structure 21 represents a common layer for the components 1, 2, 3, that is to say for the laser diode 1, the electro-absorption modulator 2 and the optical amplifier 3.

The quantum dot structure 21 is used either for amplification of the light in the laser diode 1 or in the optical amplifier 3, or for modulation in the electro-absorption modulator 2. The MQW structure 20 is used in a correspondingly complementary manner.

In the present example, with a quantum dot structure 21 and an MQW structure 20, the band gaps of the quantum dot structure 21 and of the MQW structure 20 for amplification and modulation, respectively, are chosen to be different.

In contrast to structures with identical MQWs of a quantum well type, the quantum dot structures and MQWs may be set differently for absorption and amplification, by which means it is at the same time possible to achieve low threshold currents in the laser diode 1 as well as sufficiently low optical losses and a high modulation frequency.

Together with the MQW layer 20, the quantum dot structure 21 may be produced using an epitaxy process. This considerably simplifies the production process.

P-doped layers 12 are arranged above the active layer 21. The optoelectronic device 100 has contact layers 33, 34 and contacts 31, 32. The contact layers 33, 34 are formed from highly doped semiconductor material which is conductively connected to metallic contacts. Each component 1, 2, 3 can thus be specifically supplied with current injections.

The coupling of the components 1, 2, 3 via the quantum dot structure 21 makes it possible to achieve very much higher frequencies than would be possible by using an MQW structure on its own.

Owing to the wells 5, 6, the first embodiment has a high level of optical decoupling and a high level of electrical decoupling between the components 1, 2, 3, so that the components can be controlled individually in a simple manner.

Fundamentally, FIG. 2 describes the same structure of an optoelectronic device, so that reference is made to what has been said above.

In contrast to the first embodiment, the components 1, 2, 3 in the second embodiment are not separated by wells 5, 6, so that there is a low level of optical decoupling and a low level of electrical decoupling. This is actually advantageous for fast switching processes.

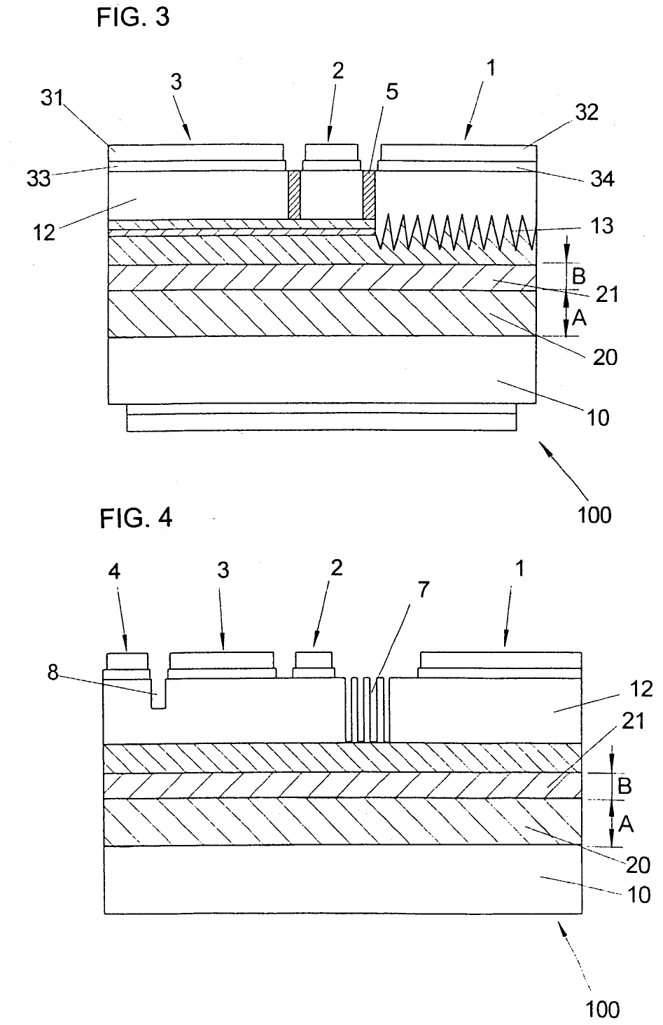

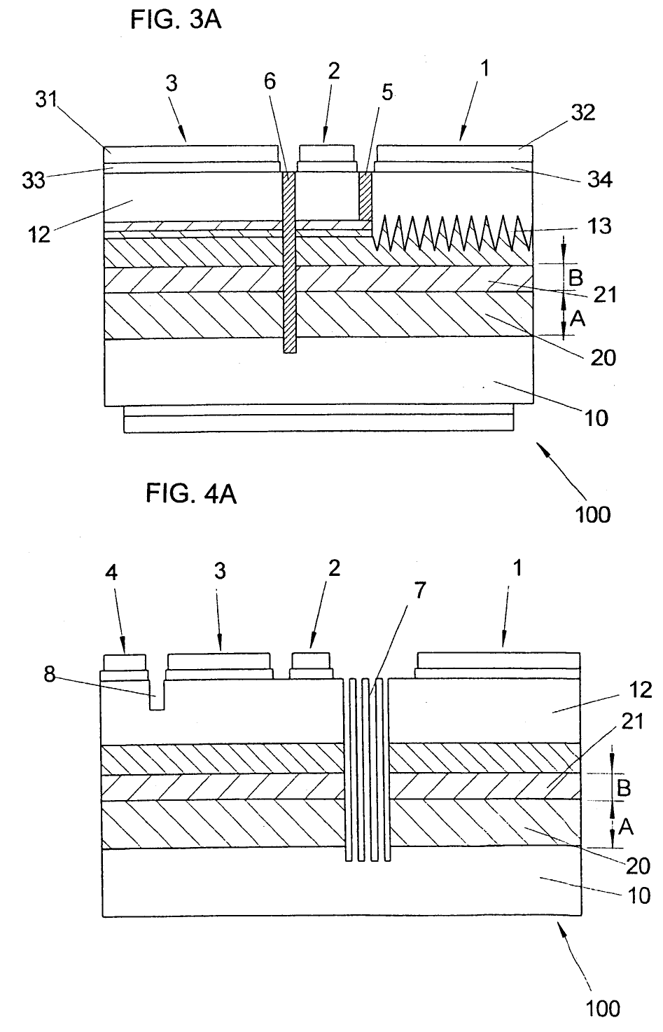

The third embodiment, which is illustrated in FIG. 3, is similar to the first embodiment, since, in this case too, wells 5, 6 are arranged between the components 1, 2, 3. The electrical isolation is, however, in this case achieved by means of ion implantation, which results in a low level of optical decoupling but a high level of electrical decoupling. The wells 5, 6 and the ion-implanted areas may also alternatively extend further into the depth of the semiconductor material, in particular as far as the n-doped layers 10.

In a modification of the third embodiment as shown in FIG. 3A, the second well 6 is incorporated such that it extends into the n-doped layer 10. The ions can likewise be implanted to the same depth.

The fourth embodiment, shown in FIG. 4, has a photodetector 4 as a further component, as distinct from the first three embodiments. In this case, a deep Bragg structure 7 is arranged between the laser diode 1 and the electro-absorption modulator 2. The Bragg structure 7 is between 2 and 50 μm wide. The individual vertical layers of the Bragg structure 7 have a minimum width of less than 1 μm, and a maximum width of a few micrometers.

The Bragg structure 7 ensures a high level of optical and electrical decoupling, for example between the laser diode 1 and other components, and in the longitudinal direction. The Bragg structure 7 also ensures definition of the laser resonator and of the emission wavelength. Alternatively, the Bragg structure 7 may also be arranged between other components 1, 2, 3, 4.

Furthermore, the fourth embodiment has a third well 8, which is arranged between the optical amplifier 3 and the photodetector 4. The third well 8 has a width of less than 10 μm.

The length of the electro-absorption modulator 2 is between 20 and 300 μm, that of the optical amplifier 3 is 20 to 2000 μm, and that of the photodetector 4 is 2 to 50 μm. These values may essentially also be transferred to the other exemplary embodiments.

FIG. 4A shows a modification of the fourth embodiment. The Bragg structure 7 in this case extends into the n-doped layers 10.

FIGS. 1 to 4 show various embodiments of an optoelectronic device according to the invention. The optoelectronic devices in this case have different monolithically integrated components, 1, 2, 3, 4, such as laser diodes, electro-absorption modulators, photodetectors or optical amplifiers. The combination of these components 1, 2, 3, 4 in the exemplary embodiments is only by way of example, so that other combinations of the components 1, 2, 3, 4 are also possible.

The optoelectronic device according to the invention may also be formed from any semiconductor material with so-called direct state transitions (such as III-V, II-IV material) which can be used for the individual components 1, 2, 3, 4 (for example InGaASP or InGaAlAS).

The essential feature is the use of at least one quantum dot structure 12 for functional coupling of the components 1, 2, 3, 4 in conjunction with a further quantum dot structure or MQW structures. Various exemplary embodiments for the last case have been described above. This allows the production of optoelectronic devices to be considerably simplified.

The implementation of the invention is not restricted to the preferred exemplary embodiments described above. In fact, a number of variants are feasible, which make use of the optoelectronic device according to the invention and of the method for its production in fundamentally different types of embodiments as well.

I claim:

1. An optoelectronic device, comprising:
a plurality of monolithically integrated components commonly integrated in semiconductor material; and
at least one quantum dot structure functionally coupling at least two of said monolithically integrated components to one another.

2. The optoelectronic device according to claim 1, wherein at least one of said components is functionally coupled to a further quantum dot structure.

3. The optoelectronic device according to claim 1, which further comprises a quantum well structure, and wherein at least one of said components is functionally coupled to said quantum well structure.

4. The optoelectronic device according to claim 3, wherein said at least one quantum dot structure and at least one quantum well structure can be produced in one epitaxy step.

5. The optoelectronic device according to claim 1, wherein at least one of said components is a laser diode.

6. The optoelectronic device according to claim 5, wherein said laser diode has a structure selected from the group consisting of a DFB structure and a DBR structure.

7. The optoelectronic device according to claim 1, wherein at least one of said components is an electro-absorption modulator.

8. The optoelectronic device according to claim 1, wherein at least one of said components is an optical amplifier.

9. The optoelectronic device according to claim 1, wherein at least one of said components is a photodetector.

10. The optoelectronic device according to claim 1, wherein said semiconductor material has at least one well incorporated therein between said at least two components for at least one of increased optical decoupling and increased electrical decoupling between said components.

11. The optoelectronic device according to claim 1, wherein said semiconductor material has at least one well incorporated therein between said at least two components for lowering a level of optical decoupling and increasing a level of electrical decoupling between said components, said at least one well containing implanted ions.

12. The optoelectronic device according to claim 1, which comprises at least one Bragg structure disposed in said semiconductor material, for increasing a level of optical and electrical decoupling between said at least two components.

13. A method for producing an optoelectronic device, which comprises:
providing a substrate;
in a single epitaxy step, growing a quantum dot structure as an active layer on the substrate and growing at least one of a further quantum dot structure and a further quantum well structure; and
wherein a plurality of monolithically integrated components are commonly integrated on the substrate and the quantum dot structure functionally couples at least two of the monolithically integrated components to one another.

14. A method for producing the optoelectronic device according to claim 1, which comprises:
growing a quantum dot structure as an active layer on a substrate; and
commonly integrating a plurality of monolithically integrated components and functionally coupling at least two of the monolithically integrated components to one another with the quantum dot structure.

15. The method according to claim 14, wherein the growing step comprises growing at least one of a further quantum dot structure and a further quantum well structure together with the quantum dot structure in one epitaxy step.
